(19) United States
(12) Patent Application Publication
(10) Pub. No.: US 2010/0073207 A1
(43) Pub. Date: Mar. 25, 2010

(54) Delta-Sigma Analog-to-Digital Converters and Methods to Calibrate Delta-Sigma Analog-to-Digital Converters

(75) Inventors: Amit Kumar Gupta, Plano, TX (US); Karthikeyan Soundarapandian, Plano, TX (US); Yong-In Park, Allen, TX (US); Wern Ming Koe, Irving, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/235,348

(22) Filed: Sep. 22, 2008

(51) Int. Cl. H03M 3/00; H03M 1/12; H03M 1/10

(52) U.S. Cl. 341/120; 341/143; 341/155

(57) ABSTRACT

Delta-sigma analog-to-digital converters (ADCs) and methods to calibrate methods to delta-sigma ADCs are disclosed. In one particular example, a delta-sigma ADC is described, including an n-bit feedback digital-to-analog converter (DAC) having a number of unit elements, and is configured to provide a feedback signal to a summing device, which generates a difference signal based on an analog input signal and the feedback signal. An n-bit ADC is included to generate an n-bit digital signal based on the difference signal. A dynamic element matching device selects one or more unit elements in the DAC based on the n-bit digital signal. A storage device, such as a memory, stores error coefficients corresponding to the plurality of unit elements. Finally, a digital corrector is included to receive the selection of unit elements, receive error coefficients corresponding to the selected unit elements, and adjust the n-bit digital signal based on the received error coefficients.

### FIELD OF THE DISCLOSURE

This disclosure relates generally to signal processing and, more particularly, to delta-sigma analog-to-digital converters and methods to calibrate delta-sigma analog-to-digital converters.

### BACKGROUND

There are many types of analog-to-digital converters (ADC) that convert a continuous time signal (i.e., an analog signal) into a digital signal (i.e., a representation of a signal using discrete numbers). One type of ADC is a delta-sigma ADC, which generally oversamples the continuous signal by an oversampling ratio. The delta-sigma ADC implements a negative feedback path using a digital-to-analog converter (DAC), which together with a high gain in forward path shapes quantization noise out of the baseband. Then, a digital filter following the delta-sigma ADC removes the undesired higher frequencies, thereby substantially reducing the quantization noise. However, the overall linearity of a delta-sigma ADC directly depends on the linearity of the DAC in the feedback loop, since the output of the DAC feeds back right at the input of the overall loop.

### SUMMARY

Delta-sigma analog-to-digital converters (ADCs) and methods to calibrate delta-sigma ADCs are disclosed. In one particular example, a delta-sigma ADC is described, including an n-bit feedback digital-to-analog converter (DAC) having a number of unit elements, is configured to provide a feedback signal to a summing device, which is configured to generate a difference signal based on an analog input signal and the feedback signal. An n-bit ADC is also included to generate an n-bit digital signal based on the difference signal. A dynamic element matching device selects one or more unit elements in the DAC based on the n-bit digital signal. A storage device, such as a memory, stores error coefficients corresponding to the plurality of unit elements. Finally, a digital corrector is included to receive the selection of unit elements, to receive the error coefficients corresponding to the selected unit elements, and to adjust the n-bit digital signal based on the received error coefficients.

### BRIEF DESCRIPTION OF THE DRAWINGS

FIG. 1 is a block diagram of a delta-sigma analog-to-digital converter.

FIG. 2 is a block diagram of a delta-sigma analog-to-digital converter that implements dynamic element matching.

FIG. 3 is a block diagram of a delta-sigma analog-to-digital converter that implements digital correction.

FIG. 4 is a block diagram of an example delta-sigma analog-to-digital converter coupled to a calibration system.

FIG. 5 is a flowchart of an example process to calibrate the example delta-sigma analog-to-digital converter of FIG. 4.

FIG. 6 is a block diagram of an example delta-sigma analog-to-digital converter during normal operation.

FIG. 7 is a chart that illustrates the example code rotation scheme of the example process of FIG. 6.

FIG. 8 is a flowchart of an example process the digital corrector of FIG. 4 may implement to correct noise.

### DETAILED DESCRIPTION

Delta-sigma analog-to-digital converters (ADC) and methods to calibrate the same are disclosed herein. In some examples, a high-resolution delta-sigma ADC implements dynamic element matching techniques and digital correction for low power, broadband operation. Although the example methods and apparatus described herein generally relate to high-resolution broadband ADCs, the disclosure is not limited to such. On the contrary, the teachings of this disclosure may be applied in any electronics device that would benefit from noise correction.

Example delta-sigma ADCs and methods to calibrate the same are disclosed. As described herein, the example low power delta-sigma ADCs having a low oversampling ratio, generally eight or less, and implements both dynamic element matching techniques and digital correction. Prior to this disclosure, it was impractical to implement dynamic element techniques into delta-sigma ADCs that have an oversampling ratio of eight or less without sacrificing noise performance. In addition, the digital correction implements an error correction technique that has a resolution lower than the resolution of the example delta-sigma ADC, thereby requiring significantly less time to calibrate. Prior to this disclosure, digital correction required a high-resolution calibration that was impractical to implement in high volume manufacturing processes. The disclosed example calibration technique has a lower resolution than the delta-sigma ADC, thereby making such a calibration simple to implement in high volume testing processes of the example delta-sigma ADCs.

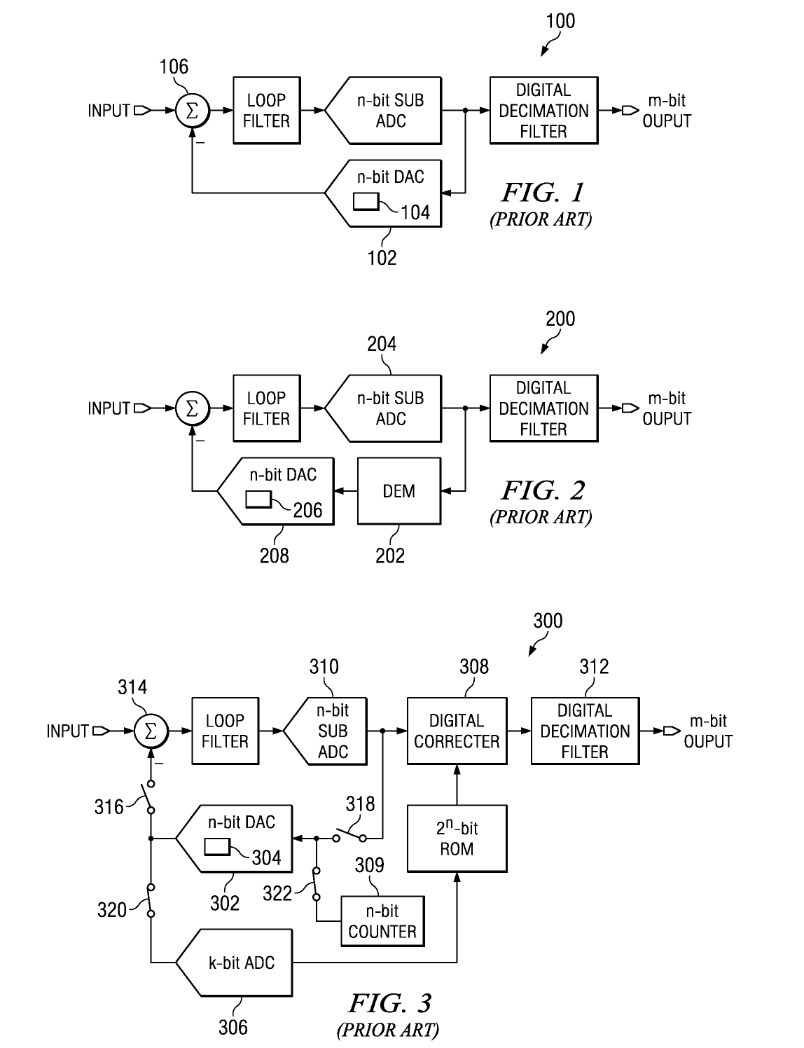

FIG. 1 illustrates a delta-sigma ADC 100 including a negative feedback path implemented by a digital-to-analog converter (DAC) 102, which receives n-bits of digital information and forms an analog feedback signal based thereon. The n-bit DAC 102 includes one or more data conversion unit elements 104 that convert a digital signal into the analog feedback signal. A subtractor 106 of the delta-sigma ADC 100 receives an input analog signal and subtracts the feedback signal therefrom, creating a difference signal. This difference signal may be referred to as the delta part of the delta-sigma converter. The resulting difference signal is processed by a loop filter and then converted from an analog signal into a digital signal. The overall accuracy of the delta-sigma ADC 100 is directly dependent on the feedback signal formed by the n-bit DAC 102.

However, the DAC 102 generally has errors associated with its operation. In the n-bit DAC 102, the unit elements 104 are generally implemented by capacitors or current sources associated with each code of the n-bit DAC 102. The unit elements 104 are implemented to convert a digital signal into an analog signal that substantially represents the digital signal. Thus, the n-bit DAC has 2ⁿ unit elements 104 to allow the n-bit DAC 102 to represent 2ⁿ different voltage levels representative of the 2ⁿ codes. Generally, the n-bit DAC 102 receives an n-bit digital signal and actuates the appropriate unit elements 104, which generates the correct output voltage. The output of the n-bit DAC 102 is the sum of the voltages of the actuated unit elements 104, which forms the feedback analog signal that substantially represents the n-bit digital signal.

In semiconductor processes to manufacture integrated circuits, such as the delta-sigma ADC 100, the unit elements 104 may vary slightly in value (e.g., capacitance, current). As a result, the output voltage of the DAC unit elements 104 may vary due to the unit element mismatches. This leads to non-linearity in the feedback n-bit DAC 102 which directly translates as non-linearity of delta-sigma ADC 100. In FIG. 1, even 0.1% mismatch in the unit elements 104 causes significant amounts of distortion to be introduced via the DAC 102.

One method to improve the performance of the feedback path of a delta-sigma ADC is to use dynamic element matching techniques, which improve the linearity performance of the ADC at the cost of increased noise. FIG. 2 illustrates a block diagram of a delta-sigma ADC 200 that implements dynamic element matching. A DEM device 202 receives an n-bit digital code from an n-bit ADC 204. The DEM device 202 selects one or more unit elements 206 from a feedback DAC 208 to generate an analog representation of the n-bit digital code.

There are different techniques to implement DEM logic. DEM techniques will always increase the noise in the device due to mismatches in unit elements, which are caused by limits in unit element matching that can be achieved in integrated circuit processes. The amount of noise degradation depends on the DEM technique used, as well as the level of unit element matching achieved. Techniques differ on how to select DAC elements 206 for a given code from the n-bit ADC 210. Random selection of unit elements 206 provides the best linearity but results in poorer noise performance. Tones in the spectrum are converted to white noise, which is directly proportional to mismatch in the unit elements 206. A technique called data weighted averaging (DWA) provides a first-order shaping of mismatch noise, thus improving noise performance. Noise introduced by DWA algorithms is also directly proportional to mismatch in the unit elements 206 to an extent that reducing unit element 206 mismatch by 50% provides a 6 dB reduction in noise. The DWA technique works very well for high oversampling ratios (e.g., >8), but when using low oversampling ratios (e.g., 4-8) the noise performance of the ADC 200 is limited by mismatch-induced noise.

Another method of improving the DAC in the feedback path of a delta-sigma ADC is to digitally correct for errors introduced by the DAC. FIG. 3 is a block diagram of a delta-sigma analog-to-digital converter 300 that implements digital correction. As described above, an n-bit DAC 302 introduces linearity errors in the delta-sigma ADC 300 as a result of mismatch error of unit elements 304. To correct for these errors, the delta-sigma ADC 300 includes an n-bit counter 309 that is used during a calibration phase to generate n-bit digital codes, and the n-bit DAC 302 generates analog representations of the n-bit digital codes. An m-bit linear calibration ADC 306 measures the mismatch errors of the unit elements 304 and stores the mismatch errors as error coefficients in a digital corrector 308. During operation, the digital corrector 308 receives a digital signal from an n-bit sub ADC 310 and, using the error coefficients, calibrates out the errors introduced by the n-bit DAC 302.

The error coefficients measured by the calibration ADC 306 and stored in the digital corrector 308 must have a resolution of at least the overall resolution of the delta-sigma ADC 300. This leads to a significant increase in word length of the signal feeding a digital decimation filter 312 and, thus, increasing the complexity of the delta-sigma ADC 300. Further, calibrating to the resolution of the delta-sigma ADC 300 may need a long calibration time. The calibrating ADC 306 must have a linearity of at least the overall delta-sigma ADC 300 linearity. For example, if the calibrating ADC 306 has a resolution of k bits, the calibrating ADC 306 calibrates to a resolution of m bits by taking an average of 2^{2(m-k)} measurements of the n-bit DAC 302 output voltages and using the average to calculate the error coefficients. Thus, calibration time is exponentially related to the calibration accuracy. If the calibration is done one time during manufacturing, increased accuracy will lead to significantly increased test times. To set up calibration, the n-bit DAC 302 is disconnected from the n-bit sub ADC 310 and a subtractor 314 by opening switches 316 and 318, and connected to the k-bit ADC 306 and the n-bit counter 309 by closing switches 320 and 322.

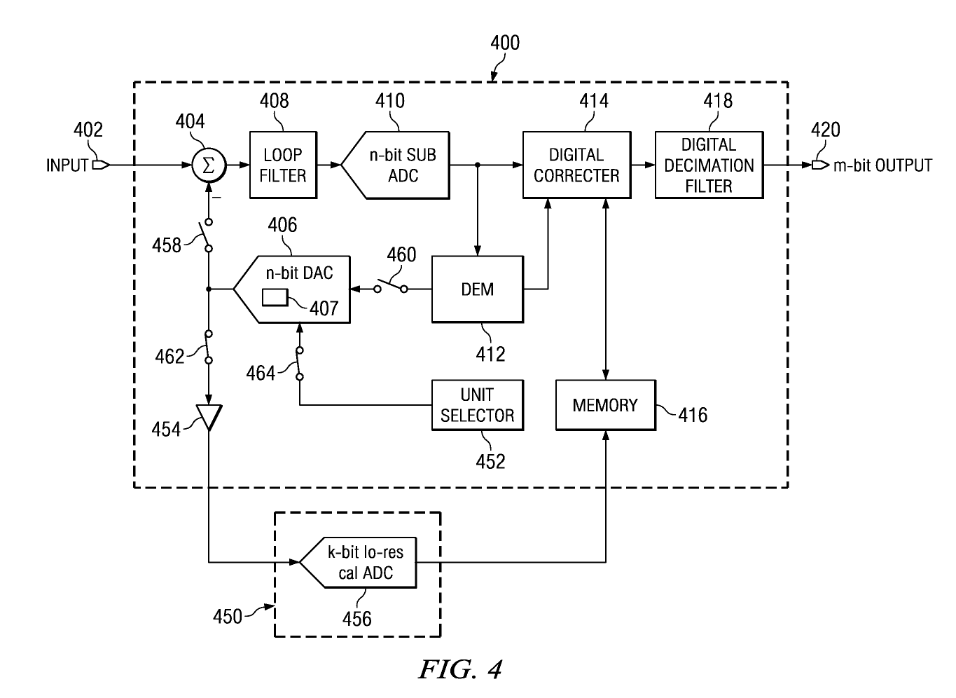

FIG. 4 is a block diagram of an example delta-sigma ADC 400 coupled to a calibration system 450. The example delta-sigma ADC 400 implements a combination of dynamic element matching and digital correction to achieve high resolution and linearity with low oversampling ratios. In the example of FIG. 4, an input 402 conveys an analog signal to a subtractor 404, which is coupled to an n-bit DAC 406 having one or more unit elements 407. The subtractor 404 is also coupled to a loop filter 408, which is further coupled to an n-bit sub ADC 410. The n-bit sub ADC 410 is coupled to the n-bit DAC 406 via a DEM device 412. In addition, the n-bit sub ADC 410 is further coupled to a digital corrector 414, which is coupled to a memory device 416 and a decimation filter 418. The decimation filter 418 is coupled to an output 420 of the ADC 410. Normal operation of the delta-sigma ADC 400 may commence after a calibration phase, and is discussed below in connection with FIG. 6.

As discussed in connection with FIG. 2 above, noise performance with DEM is limited by mismatch in DAC elements. For every bit of improvement in mismatch error, there is a 6 dB improvement in noise performance. The digital correction can be used to reduce mismatch errors and then noise performance can be further improved using DEM. Some advantages of doing DEM in combination with digital correction over doing only digital correction include a reduced word length from the digital corrector to the digital decimation filter and reduced calibration time.

In the illustrated example, the delta-sigma ADC 400 is calibrated during, for example, manufacturing. An example calibration system 450 is coupled to the example delta-sigma ADC 400 to calibrate the same. The example calibration system 450 includes a control device 452 that is coupled to the n-bit DAC 406. The n-bit DAC 406 is also coupled to a buffer 454, which is further coupled to a k-bit calibration ADC 456. The calibration ADC 456 is coupled to the memory device 416 to store error coefficients therein. During calibration, the n-bit DAC 406 is decoupled from the remainder of the delta-sigma ADC 400 as shown via switches 458 and 460, the n-bit DAC 406 is coupled to the buffer 454 via a switch 462, and the unit selector 452 is coupled to the n-bit DAC 406 via a switch 464. In contrast, during normal operation (as shown below in FIG. 6) the switches 458 and 460 are closed to couple the n-bit DAC 406 to the subtractor 404 and the DEM device 412, and switches 462 and 464 are open to decouple the n-bit DAC 406 from the calibration system 450.

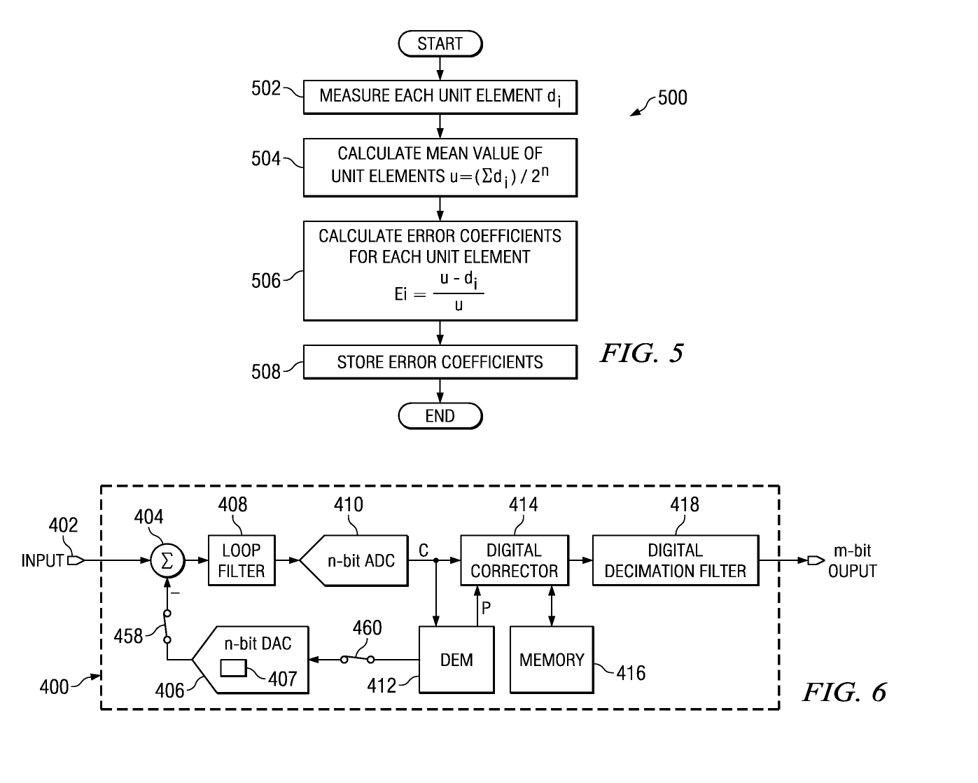

During manufacturing, the example calibration system 450 measures the error coefficients of the unit elements 407 and stores the results in the memory 416. FIG. 5 illustrates an example process 500 that the example calibration system 450 may implement to determine the errors of the unit elements 407. Initially, the example process 500 causes the control device 452 to actuate each unit element 407 of the n-bit DAC 406 individually and measure the output value dᵢ for each unit element 407 (block 502). In particular, the selected unit element 407 outputs a voltage and the buffer 452 interfaces the output voltage with the calibration ADC 456. The calibration ADC 456 converts the voltage from the corresponding unit element 407 into a digital signal representative of its voltage. Measurement accuracy can be improved by taking multiple samples of the calibration ADC 456 output and taking their average as the digital representative of the output value of the unit element 407. In the example techniques described, the linearity requirement on the calibrating ADC is relaxed because only one unit element is selected at a time. In contrast, prior calibration techniques measured the full range of output voltages as represented by the unit elements, resulting in very high linearity requirements for the calibrating ADC.

After measuring the value dᵢ of each unit element 407 at block 502, the example process 500 determines the mean value u of the unit elements 407 (block 504). In the illustrated example, because the actual value of the each unit element 407 is not known, the error is thus determined by the difference the mean value u and measured values dᵢ. Thus, after determining the mean value u of the unit elements 407, the example process 500 calculates the error of each of the unit elements 407 based on the mean value of the unit elements (block 506). The error coefficient Eᵢ for each unit element 407 is obtained by dividing the error value by the mean value u as shown in Equation 1:

$${E}_{i} = \frac{u - {d}_{i}}{u} . \qquad ( Eq . 1 )$$

After computing the error coefficients Eᵢ of the unit elements 407, the example process 500 stores the resulting error coefficients Eᵢ in the memory device 416, for example (block 508). The example process 500 ends after the error coefficients Eᵢ are stored in the memory device 416.

In the example of FIG. 4, all or part of calibration system 450 can be implemented into the example delta-sigma ADC 400. However, in the illustrated example, the calibration system 450 is preferably configured external to the delta-sigma ADC 400 to reduce its physical size, thereby conserving valuable space at the integrated circuit level. The example buffer amplifier 454 is implemented in the example delta-sigma ADC 400 to directly interface the same with the ADC 456 of the calibration system 450, such as a Teradyne Catalyst tester. The unit selector 452 is also included in the delta-sigma ADC 400 for calibration purposes. It should be noted that the calibration techniques described herein may be used to reduce the calibration time of any delta-sigma ADC that uses error coefficients for digital correction.

FIG. 6 is a block diagram of an example delta-sigma analog-to-digital converter during normal operation. In the example of FIG. 6, the delta-sigma ADC 400 converts an analog signal into an m-bit (e.g., 20 bit, 24 bit) digital signal that is substantially representative of the input analog signal. In particular, the analog signal is conveyed to the subtractor 404 via the input 402. An n-bit DAC 406 (e.g., the calibrated n-bit DAC of FIG. 4) forms and conveys a feedback analog signal to the subtractor 404. In response, the subtractor 404 subtracts the feedback analog signal from the first analog signal to shape the quantization noise in the example delta-sigma ADC 400.

The resulting analog signal is conveyed to a loop filter 408 which amplifies and integrates the analog signal, thereby shifting noise from lower frequencies to higher frequencies. The loop filter 408 conveys the integrated analog signal to an n-bit sub ADC 410, which generates a digital signal having n-bits of resolution (e.g., 3-5 bits). Traditionally, the delta-sigma ADC 400 samples the analog signal at a rate much greater than the highest frequency of interest (e.g., an OSR of 8). In the illustrated example, the delta-sigma ADC 400 is generally configured to have a large bandwidth (e.g., 5 megahertz) and an oversampling ratio of eight. Due to the large bandwidth of the delta-sigma ADC 400, the example delta-sigma ADC 410 typically has an oversampling ratio of eight or less.

The n-bit digital signal is conveyed from the ADC 410 to a dynamic element matching (DEM) device 412 to form a negative feedback path. The DEM device 412 is coupled to the n-bit DAC 406 and shapes the unit element mismatch noise to higher frequencies outside the frequency band of interest. That is, the n-bit DAC 406 receives the digital signal from the DEM device 412 and, in response, forms the second analog signal. However, the DEM device 412 selects the unit elements 407 of the n-bit DAC 406 to be actuated according to DEM techniques (e.g., DWA), which thereby transfers noise introduced by the n-bit DAC 406 from lower frequencies to higher frequencies.

More particularly, the DEM device 412 is configured to shape the mismatch noise associated with the unit elements 407 of the n-bit DAC 406. As described above, one method to remove errors associated with the unit elements 407 of the n-bit DAC 406 is to perform dynamic element matching techniques using data weighted averaging, for example. Data weighted averaging generally implements a high pass transfer function that shifts the noise introduced by the unit elements 407 of the n-bit DAC 406 from lower to higher frequencies. The noise is shifted to higher out-of-band frequencies that are removed by the digital decimation filter 418. To perform data weighted averaging, the DEM device 412 is configured to cause the n-bit DAC 406 to rotate through its unit elements 407 (i.e., the capacitors in the n-bit DAC 406) such that each unit element 407 is used substantially the same number of times. In other words, the DEM device 412 configures the n-bit DAC 406 so that each unit element 407 is used substantially equally, thereby averaging the errors of the unit elements 407.

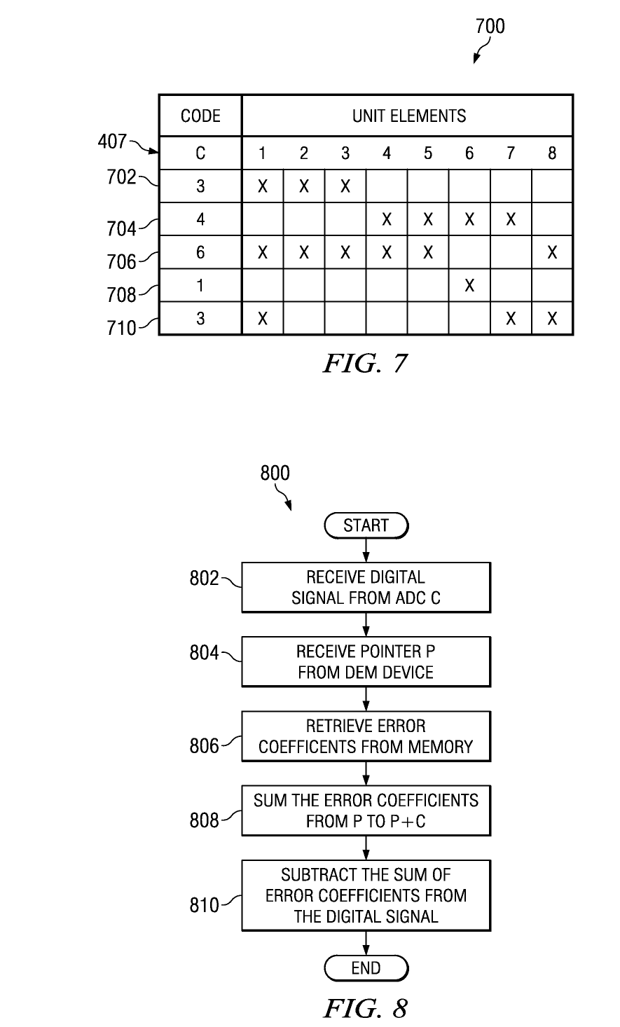

FIG. 7 illustrates an example chart 700 that represents the operation of the example DEM 412 using different codes. In the example of FIG. 7, the columns represent the unit elements 407 and the rows represent the digital codes C that the example DEM 412 receives. The cells of the chart 700 are marked if their corresponding unit element 407 is selected based on the example DEM 412.

At the outset, the example DEM 412 receives a first code 702, which is three. In response, the example DEM 412 actuates the corresponding unit elements 407 of the n-bit DAC 406 to output a voltage that is substantially representative of three. Of course, the unit elements 407 may have mismatch errors and, as a result, the voltage output by the n-bit DAC 406 may vary for each selected unit element 407. Initially, there the example DEM 412 has a pointer of zero and, thus, the example DEM 412 selects and actuates the first, second, and third unit elements 407. In addition, the example DEM 412 determines the pointer is three.

In response a second code 704, which is four, the example DEM 412 selects the fourth, fifth, sixth, and seventh unit elements 407 and determines the pointer to be seven. In response to a third code 706, which is six, the example DEM 412 selects the eighth unit element 407. Of course, to output a voltage substantially representative of six, the example DEM 412 rotates back to the first unit element, thereby selecting the first through the fifth unit elements 407. In the example of FIG. 7, the example DEM 412 determines the pointer to be five in response to the third code 706. As illustrated by a fourth code 708 and a fifth code 710, the example DEM 412 continually rotates through the different unit elements 407 such that they are used a substantially equal number of times. Of course, the data weighted averaging algorithm illustrated in the example of FIG. 6 is an example of one type of dynamic element matching, and any other suitable dynamic element matching technique may be implemented in the DEM device 412 (e.g., second-order shaping).

As described above, the n-bit sub ADC 410 also conveys the digital signal to a digital corrector 414 coupled to a memory device 416. As described above, the unit elements 407 of the n-bit DAC 406 are not precisely equal to each other. As a result, the voltage output by the unit elements 407 may differ, thereby causing the feedback analog signal formed by the n-bit DAC 406 to have both distortion and noise. The digital corrector 414 corrects for the mismatch errors in the unit elements 407 by, for example, subtracting error coefficients that are stored in the memory 416 from the digital signal. However, as described above, the DEM device 412 causes the n-bit DAC 406 to rotate through its different unit elements 407 and the digital corrector 414 itself is unable to determine which of the unit elements 407 are selected in the n-bit DAC 406. Thus, to determine the errors of the selected unit elements 407, the digital corrector 414 receives an information signal (e.g., a pointer P) from the DEM device 412 indicative of the offset to determine the selected unit elements 407 in combination with the digital code C.

FIG. 8 illustrates an example process 800 the digital corrector 414 of FIG. 6 may implement to correct the digital signal. Initially, the example process 800 receives the digital signal (e.g., digital code C) from the n-bit sub ADC 410 (block 802) and the information signal (e.g., pointer P) from the DEM device (block 804). The example process 800 then determines which of the unit elements 407 the DEM device 412 selected and reads the corresponding error coefficients that are stored in the memory device 416 (block 806). After determining the errors of the selected unit elements 407, the example process 800 sums the error coefficients from P to P+C (block 808). The sum of the error coefficients is subtracted from the digital signal (block 810). After subtracting the error coefficients from the digital signal, the example process 800 ends.

Thus, in the illustrated example, the digital corrector 414 thereby corrects for errors as a result of unit element 407 mismatches within the n-bit DAC 406. However, at the same time, the digital corrector 414 also corrects for mismatch noise introduced by the unit elements 407. In particular, the mismatches of the unit elements 407 cause mismatch noise, which are introduced during dynamic element matching and the digital corrector 414 calibrates out (i.e., removes) the mismatch noise by correcting for the mismatches in the unit elements 407.

The digital corrector 414 conveys the resulting discrete signal to a digital decimation filter 418 that filters out high frequency content of the discrete signal by any suitable method. In the illustrated example, the digital decimation filter 418 reduces the number of samples, thereby removing high frequency content from the discrete signal. As a result, the combined operation of the loop filter 408 and the n-bit DAC 406 shape the quantization noise generated by the n-bit sub ADC 410 out of the baseband. The DEM device 412 improves the linearity performance of the n-bit DAC 406 while utilizing data weighted averaging techniques to shape mismatch noise out of the baseband. Finally, the digital decimation filter 418 removes quantization and mismatch noise from the out-of-band frequencies of the discrete signal. The output of the digital decimation filter 418 is conveyed to an m-bit output 420 of the delta-sigma ADC 400 to interface with other devices and/or circuits.

Although certain example methods and apparatus are described herein, other implementations are possible. The scope of coverage of this patent is not limited to the specific examples described herein. On the contrary, this patent covers all methods and apparatus falling within the scope of the invention.

What is claimed is:

1. A delta-sigma analog-to-digital converter (ADC), comprising:
an n-bit feedback digital-to-analog converter (DAC) configured to provide a feedback signal, comprising a plurality of unit elements;
a summing device configured to generate a difference signal based on an analog input signal and the feedback signal;
an n-bit ADC configured to generate an n-bit digital signal based on the difference signal;
a dynamic element matching device configured to select one or more unit elements in the feedback DAC based on the n-bit digital signal;
a storage device configured to store a plurality of error coefficients corresponding to the plurality of unit elements; and
a digital corrector configured to receive the selection of unit elements, to receive the error coefficients corresponding to the selected unit elements, and to adjust the n-bit digital signal based on the received error coefficients.

2. A delta-sigma ADC as defined in claim 1, further comprising a decimation filter configured to generate an m-bit digital signal based on the adjusted n-bit digital signal.

3. A delta-sigma ADC as defined in claim 2, wherein the m-bit digital signal has a higher resolution than the n-bit digital signal.

4. A delta-sigma ADC as defined in claim 2, wherein the stored error coefficients have a resolution greater than the n-bit digital signal and less than the m-bit digital signal.

5. A delta-sigma ADC as defined in claim 1, wherein the digital corrector is configured to subtract a sum of the received error coefficients from the n-bit digital signal.

6. A delta-sigma ADC as defined in claim 1, wherein the storage device is configured to receive the plurality of error coefficients from a calibration device.

7. A delta-sigma ADC as defined in claim 1, wherein the dynamic element matching device is configured to select unit elements based on the n-bit digital signal and a previous selection of unit elements.

8. A delta-sigma ADC as defined in claim 1, wherein the dynamic element matching device is configured to select unit elements based on data weighted averaging.

9. A delta-sigma ADC as defined in claim 1, wherein the delta-sigma ADC has an oversampling ratio of eight or less.

10. A delta-sigma ADC as defined in claim 1, wherein receiving the selection of unit elements comprises receiving the n-bit digital signal from the n-bit ADC.

11. A method to calibrate a delta-sigma analog-to-digital converter (ADC), comprising:
measuring an output voltage of a first unit element of a plurality of unit elements in a feedback digital-to-analog converter (DAC);
determining a mean output voltage based on the plurality of unit elements;
determining an error coefficient of the first unit element based on the measured output voltage and the mean output voltage; and
storing the error coefficient in a storage device.

12. A method as defined in claim 11, further comprising:
selecting the first unit element;
deselecting the first unit element; and
selecting a second unit element of the plurality of unit elements.

13. A method as defined in claim 12, further comprising determining a second error coefficient of the second unit element based on a second measured output voltage and the mean output voltage.

14. A method as defined in claim 11, further comprising measuring an output voltage of each unit element of the plurality of unit elements.

15. A method as defined in claim 14, wherein determining the mean output voltage comprises determining a mean of the output voltages of the plurality of unit elements.

16. A method as defined in claim 11, wherein determining the error coefficient of the first unit element comprises determining a difference between the measured output voltage of the first unit element and the mean output voltage.

17. A method as defined in claim 11, wherein measuring the output voltage of the first unit element comprises generating a digital signal representative of the output voltage.

18. A method as defined in claim 17, wherein the digital signal has a linearity less than a linearity of a delta-sigma ADC being calibrated.

19. A method as defined in claim 11, further comprising generating a plurality of digital signals representative of a plurality of measurements of the output voltage of the first unit element.

20. A system to provide a calibrated delta-sigma analog-to-digital converter (ADC), comprising:
an n-bit feedback digital-to-analog converter (DAC) configured to provide a feedback signal, comprising a plurality of unit elements;
a storage device configured to store a plurality of error coefficients corresponding to the plurality of unit elements;
a calibration system, configured to:
select one of the plurality of unit elements in the feedback DAC;
measure an output voltage of the selected unit element;
determine a mean output voltage based on measuring an output voltage for each of the plurality of unit elements;
determine an error coefficient of the selected unit element based on the measured output voltage and the mean output voltage; and
store the error coefficient in the storage device;
a summing device configured to generate a difference signal based on an analog input signal and the feedback signal;
an n-bit ADC configured to generate an n-bit digital signal based on the difference signal;
a dynamic element matching device configured to select one or more unit elements in the DAC based on the n-bit digital signal;
a digital corrector configured to receive the selection of unit elements, to receive error coefficients corresponding to the selected unit elements, and to adjust the n-bit digital signal based on the received error coefficients.
